(19) United States
(12) Patent Application Publication
(10) Pub. No.: US 2004/0207450 A1
(43) Pub. Date: Oct. 21, 2004

(54) Voltage level shifter and system mounting voltage level shifter therein

(75) Inventor: Kazumasa Ando, Chiba-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/776,250

(22) Filed: Feb. 12, 2004

(30) Foreign Application Priority Data
Feb. 24, 2003 (JP) P2003-045390

(51) Int. Cl. H03L 5/00

(52) U.S. Cl. 327/333

(57) ABSTRACT

A voltage level shifter comprises a level changer and an output circuit. The level changer has a current block and a first transistor. A high voltage power supply higher than the potential of the low voltage power supply or the current block is connected to a source or a drain of the first transistor. The level changer outputs a potential of the high voltage power supply or a reference potential by a potential of an input signal inputted into the first transistor. The output circuit outputs an output signal having amplitude between the reference potential and the potential of the high voltage power supply when a signal from an output end of the level changer is inputted thereto.

### CROSS-REFERENCE TO RELATED APPLICATIONS

This application is based upon and claims the benefit of priority from the prior Japanese Patent Application No. 2003-45390, filed Feb. 24th 2003, the entire contents of which are incorporated herein by reference.

### FIELD OF THE INVENTION

The present invention relates to a voltage level shifter, and more particularly, to a voltage level shifter for changing a voltage level of a signal to a high voltage level from a low voltage level and a system mounting the voltage level shifter therein.

### BACKGROUND OF THE INVENTION

A signal outputted from an LSI operating by a low voltage power supply is occasionally supplied to an LSI operating by a high voltage power supply. In this case, it is necessary to provide a voltage level shifter for an input port of the LSI operating by the high-voltage power supply to convert a low voltage level signal into a high voltage level signal.

When being configured by a CMOS circuit, a conventional voltage level shifter has the following configuration. Two pairs of serial circuits of P-channel MOSFETs (hereinafter, referred to as “PMOSs”) and N-channel MOSFETs (hereinafter, referred to as “NMOSs”), which are connected to a high voltage power supply, are provided. Drain output ends of the PMOSs are mutually connected to gates of the PMOSs of the other pair. Signals with low voltage level amplitude and mutually reversed polarities are inputted into gates of the NMOSs. Output signals with high voltage level are obtained from the drain output end of one of the PMOSs (e.g., refer to Yasoji Suzuki, “Applied Technique of CMOS,” Fifth Edition, Sanpo Publications, Inc., Feb. 15th, 1982, p29-30).

FIG. 1 is a circuit diagram showing a configuration example of this conventional voltage level shifter. In the example, the voltage level shifter is configured by a level changer 101 and an output CMOS inverter 106.

Level changer 101 is provided with a first CMOS inverter 102 and a second CMOS inverter 103. First CMOS inverter 102 is configured by complementarily connected PMOS 111 and NMOS 121 and supplied with a low voltage power supply VDD1. Second CMOS inverter 103 is configured by complementarily connected PMOS 112 and NMOS 122 and supplied with low voltage power supply VDD1.

Level changer 101 has a PMOS 113, a PMOS 114, an NMOS 123, and an NMOS 124. Sources of PMOS 113 and PMOS 114 are connected to a high voltage power supply VDD2. A source of NMOS 123 and NMOS 124 is connected to a reference potential VSS. Drains of PMOS 113 and NMOS 123 are connected to each other. Drains of PMOS 114 and NMOS 124 are connected to each other.

The drain of PMOS 114 (common with the drain of NMOS 124) is connected to a gate of PMOS 113. The drain of PMOS 113 (common with the drain of NMOS 123) is connected to a gate of PMOS 114. The drain of PMOS 114 is an output end 133 of level changer 101.

In the configuration, an input signal IN with low voltage level amplitude is an input signal of first CMOS inverter 102. An output signal from an output end 131 of first CMOS inverter 102 is an input signal of second CMOS inverter 103. An output signal from output end 131 of first CMOS inverter 102 is a gate input signal of NMOS 123. An output signal from an output end 132 of second CMOS inverter 103 is a gate input signal of NMOS 124. Finally, an output signal of level changer 101 is outputted from output end 133.

The output signal from output end 133 of level changer 101 is inputted into CMOS inverter 106. CMOS inverter 106 is constituted of complementarily connected PMOS 117 and NMOS 127. CMOS inverter 106 is supplied with high voltage power supply VDD2, and the output CMOS inverter 106 is an output signal OUT with high voltage level amplitude.

Reference potential VSS is given to the sources of the aforementioned NMOSS 121 to 124 and 127.

The operation of the voltage level shifter with the aforementioned configuration is as follows.

First, when input signal IN is at an H level (VDD1), output end 131 of first CMOS inverter is at an L level (VSS). Output end 132 of second CMOS inverter 103 is at the H level (VDD1) NMOS 124 is conductive, and NMOS 123 is non-conductive.

Since NMOS 124 is conductive, the drain potential thereof becomes reference potential VSS. PMOS 113, the gate input of which is the drain of NMOS 124, is conductive. The drain potential of PMOS 113 is at an H level (VDD2). PMOS 114, in which the drain potential of the PMOS 113 is given to the gate input, is non-conductive. By this operation, output end 133 of level changer 101 is at reference potential VSS, the drain potential of NMOS 124.

Output CMOS inverter 106 reverses the level of output end 133 of level changer 101. Output signal OUT from CMOS inverter 106 is at the H level (VDD2). In other words, input signal IN at the VDD1 level is converted into output signal OUT at the VDD2 level.

Meanwhile, when input signal IN is at the L level (VSS), output end 131 of first CMOS inverter 102 is at the H level (VDD1) Output end 132 of second CMOS inverter 103 is at the L level (VSS). NMOS 123 is conductive, and NMOS 124 is non-conductive.

Since NMOS 123 is conductive, the drain potential thereof becomes reference potential VSS. PMOS 114, the gate input of which is the drain of NMOS 123, is conductive. The drain potential of PMOS 114 is at the H level (VDD2). PMOS 113, in which the drain potential of the PMOS 114 is given to the gate input, is non-conductive. By this operation, output end 133 of level changer 101 is at the drain potential (VDD2) of PMOS 114.

Output CMOS inverter 106 reverses the level of output end 133 of level changer 101. Output signal OUT from inverter 106 is at the L level (VSS).

Output CMOS inverter 106 has a function to reinforce the driving forces of NMOSs 123 and 124 of level changer 101. NMOSs 123 and 124 are given low voltage to the gates and have weak driving forces.

### SUMMARY OF THE INVENTION

A voltage level shifter according to an embodiment of the present invention comprises a level changer having a current block and a first transistor, in which an input signal having amplitude between a reference potential and a potential of a low voltage power supply higher than the reference potential is inputted into a gate of the first transistor, a high voltage power supply higher than the potential of the low voltage power supply or the current block is connected to a source or a drain of the first transistor, and the level changer outputs a potential of the high voltage power supply or the reference potential by a potential of the input signal inputted into the first transistor, and an output circuit for outputting an output signal having amplitude between the reference potential and the potential of the high voltage power supply when a signal from an output end of the level changer is inputted thereto.

A system mounting according to another embodiment of the present invention a voltage level shifter therein, the system comprising a peripheral circuit, the voltage level shifter connected to the peripheral circuit, and an internal circuit connected to the level shifter, wherein the voltage level shifter comprises a level changer having a current block and a first transistor, in which an input signal having amplitude between a reference potential and a potential of a low voltage power supply higher than the reference potential is inputted into a gate of the first transistor from the peripheral circuit, a high voltage power supply higher than the potential of the low voltage power supply or a current block is connected to a source or a drain of the first transistor, and the level changer outputs a potential of the high voltage power supply or the reference potential by a potential of the input signal inputted into the first transistor, and an output circuit for outputting an output signal having amplitude between the reference potential and the potential of the high-voltage power supply to the internal circuit when a signal from an output end of the level changer is inputted thereto.

### BRIEF DESCRIPTION OF THE DRAWINGS

FIG. 1 is a circuit diagram showing a configuration example of a conventional voltage level shifter.

FIG. 2 is a diagram showing an example of a system mounting therein an LSI, which operates by different supply voltage.

FIG. 3 is a circuit diagram showing the configuration of a voltage level shifter according to a first embodiment of the present invention.

FIGS. 4A and 4B are diagrams for explaining the operation of a current block of the voltage level shifter according to the first embodiment of the present invention.

FIGS. 5A and 5B are waveform diagrams for explaining the effect of an output retainer of the voltage level shifter according to the first embodiment of the present invention.

FIG. 6 is a circuit diagram showing the configuration of a voltage level shifter according to a second embodiment of the present invention.

### DETAILED DESCRIPTION OF THE INVENTION

Hereinafter, embodiments of the present invention are described with reference to the drawings.

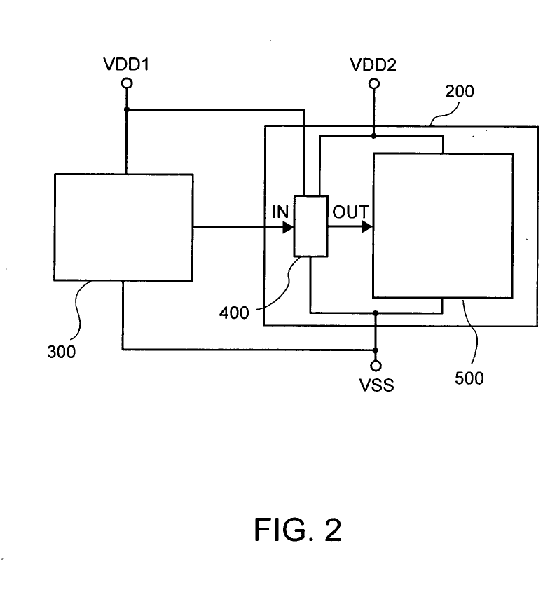

Before explaining a voltage level shifter according to an embodiment of the present invention, an example of a system employing the voltage level shifter is described. FIG. 2 shows a system mounting therein an LSI, which operates by different power supply voltage.

FIG. 2 shows an example where a signal from a peripheral LSI (peripheral circuit) 300 is inputted into a microcomputer (control circuit) 200. Microcomputer 200 operates by a high voltage power supply VDD2, and peripheral LSI 300 operates by a low voltage power supply VDD1. A voltage level shifter 400 is provided for an input port of microcomputer 200. A signal IN at a VDD1 level from peripheral LSI 300 is inputted into voltage level shifter 400. Voltage level shifter 400 converts signal IN into a signal OUT at a VDD2 level. Signal OUT is inputted into an internal circuit 500 of microcomputer 200.

Voltage level shifter 400 is supplied with both low voltage power supply VDD1 and high-voltage power supply VDD2. A reference potential VSS is shared by and supplied to microcomputer 200 and peripheral LSI 300.

In this system, it is unnecessary to operate voltage level shifter 400 constantly depending on a type of peripheral LSI 300. It is necessary to operate voltage level shifter 400 only when microcomputer 200 calls. Herein, duration voltage level shifter 400 operates upon the call from microcomputer 200 is referred to as “system operation period,” and other duration is referred to as “standby period.”

In this standby period, operation current does not flow, but off leak current flows in peripheral LSI 300. When peripheral LSI 300 has numerous elements, the off leak current flowing in peripheral LSI 300 cannot be ignored during the standby period in order to save power.

There is an example of a method for reducing the off leak current flowing in peripheral LSI 300 during the standby period. It is a method for switching the potential of low voltage power supply VDD1 of peripheral LSI 300 to reference potential VSS during the standby period.

In the system shown in FIG. 2, the potential of low voltage power supply VDD1, which is supplied to voltage level shifter 400, is also switched to reference potential VSS.

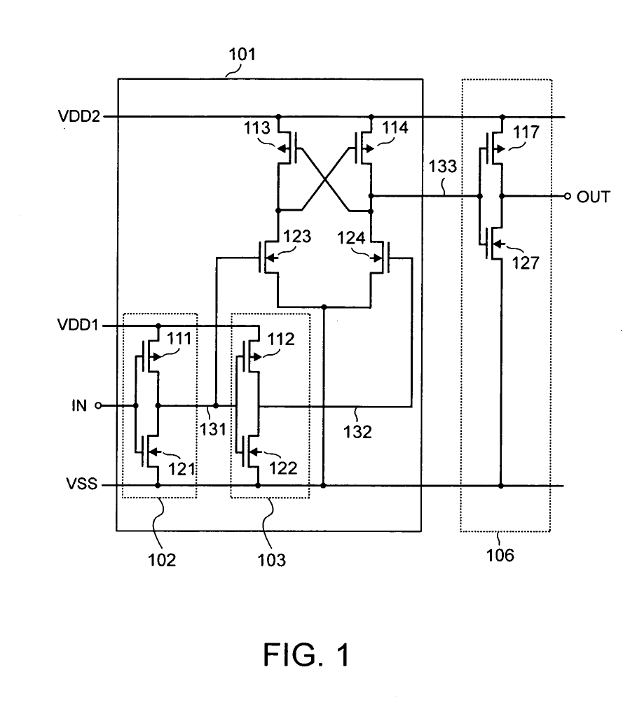

Suppose the case where voltage level shifter 400 is configured by a circuit shown in FIG. 1. Switching the potential of low voltage power supply VDD1 into reference potential VSS is a major factor in the generation of shoot-through current. The shoot-through current is current which flows from PMOSs 113 and 114 of a level changer 101 to NMOSs 123 and 124.

When the potential of low voltage power supply VDD1 is switched to reference potential VSS, output levels of both output ends 131 of first CMOS inverters 102 and output ends 132 of second CMOS inverters 103 are occasionally unstable. The operations of both NMOSs 123 and 124, the gate inputs of which are those outputs, become unstable. Both NMOSs 123 and 124 are occasionally in a weak conductive state. Drain potentials of both NMOSs 123 and 124 become unstable. The operations of PMOSs 113 and 114, the gate inputs of which are those drains, also become unstable. Both PMOSs 113 and 114 are in a weak conductive state.

In this situation, the shoot-through current flows from high-voltage power supply VDD2 to reference potential VSS through PMOS 113 and NMOS 123 and/or through PMOS 114 and NMOS 124.

In this case, the output level of output end 133 of level changer 101 becomes unstable intermediate potential. The shoot-through current also flows in output CMOS inverter 106.

When the state where the shoot-through current flows continues, lives of elements constituting the voltage level shifter are shortened. This reduces the reliability of the integrated circuit mounting the voltage level shifter therein.

In the embodiments of the present invention, described is a voltage level shifter capable of blocking the shoot-through current even when the potential of a low voltage power supply is switched from the potential of low voltage to the reference potential.

(First Embodiment)

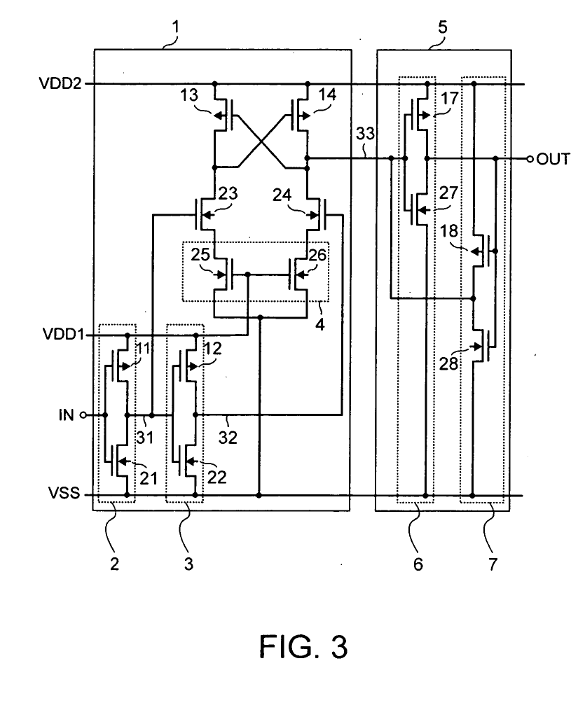

FIG. 3 is a circuit diagram showing the configuration of a voltage level shifter according to a first embodiment of the present invention. A level changer (level shifting circuit) 1 and an output retainer (output retaining circuit) 5 constitute the voltage level shifter according to the embodiment. Level changer 1 includes a current block (current block circuit) 4 for blocking shoot-through current.

The configuration of level changer 1 is described. Level changer 1 includes first and second CMOS inverters 2 and 3 of first and second input circuit. First CMOS inverter 2 is configured by complementarily connected PMOS 11 and NMOS 21. Second CMOS inverter 3 is configured by complementarily connected PMOS 12 and NMOS 22. Sources of PMOS 11 and PMOS 12 are supplied with a potential higher than reference potential VSS as a first potential from a low voltage power supply VDD1.

Level changer 1 further includes a PMOS 13, a PMOS 14, an NMOS 23, and an NMOS 24. A drain of NMOS 23 is connected to a drain of PMOS 13, and a drain of NMOS 24 is connected to a drain of PMOS 14. Sources of PMOSs 13 and 14 are supplied with a power supply potential higher than a power supply potential of low voltage power supply VDD1 as a second potential from high voltage power supply VDD2. A gate input of PMOS 13 is connected to the drain of PMOS 14 (common with a drain of NMOS 24). A gate input of PMOS 14 is connected to the drain of PMOS 13 (common with the drain of NMOS 23). The drain of PMOS 14 is an output end 33 of level changer 1.

Level changer 1 further includes current block 4. NMOSs 25 and 26 constitute current block 4. A drain of NMOS 25 is connected to a source of NMOS 23. A drain of NMOS 26 is connected to a source of NMOS 24. Gate inputs of NMOSs 25 and 26 are supplied with a power supply potential of low voltage power supply VDD1.

Sources of NMOSs 21, NMOSs 22, NMOSs 25 and NMOSs 26 are connected to a reference potential VSS.

In level changer 1, an input signal IN with low voltage level amplitude is an input signal of first CMOS inverter 2. An output signal from an output end 31 of first CMOS inverter 2 is an input signal of second CMOS inverter 3. An output signal from first CMOS inverter 2 is a gate input signal of NMOS 23. An output signal from an output end 32 of second CMOS inverter 3 is a gate input signal of NMOS 24.

The configuration of output retainer 5 is described, into which an output signal from output end 33 of level changer 1 is inputted.

Output retainer 5 is configured by an output CMOS inverter (output circuit) 6 and a feedback CMOS inverter (feedback circuit) 7. Complementarily connected PMOS 17 and NMOS 27 constitute output inverter 6. Complementarily connected PMOS 18 and NMOS 28 constitute feedback inverter 7. The inverters 6 and 7 are supplied with a power supply potential of high voltage power supply VDD2, and an output of output retainer 5 is an output signal OUT with high voltage level amplitude. Sources of NMOSs 27 and 28 are connected to reference potential VSS.

An output signal, which is outputted from output end 33 of level changer 1, is inputted into output inverter 6 of output retainer 5. Output signal OUT, the output of output inverter 6, is inputted into feedback inverter 7. The output of feedback inverter 7 is connected to an input end of output inverter 6 (i.e., output end 33 of level changer 1).

As an example, a power supply potential of low voltage power supply VDD1, a power supply potential of high-voltage power supply VDD2, and reference potential VSS are set to 1.3 to 1.7 V, 3.0 to 3.6 V (>VDD1), and 0V, respectively.

By the aforementioned connection, output inverter 6 and feedback inverter 7 form a positive feedback circuit. The positive feedback circuit functions to return the output level of output end 33 of level changer 1 to the self and retain the signal level. Response speeds of output inverter 6 and feedback inverter 7 are faster than output transition speed of level changer 1 in order to make time required for positive feedback shorter than the time required for transition of an output level of output end 33 in level changer 1.

The operation of the voltage level shifter of the embodiment is described. Mainly explained is the operation when the voltage level shifter of the present embodiment is installed in a system capable of switching the potential of low voltage power supply VDD1 to reference potential VSS. Specifically, described is the operation when the voltage level shifter is installed in the system used by switching the potential during the standby period as explained with reference to FIG. 2.

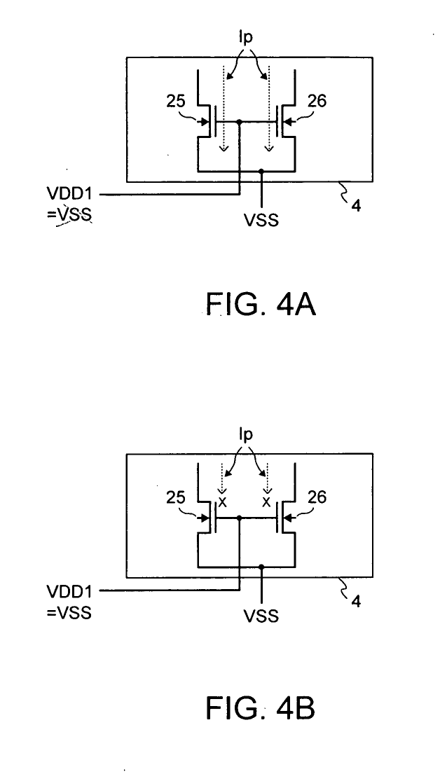

When the potential of low voltage power supply VDD1 is a normal potential for system operation, gate-source voltages of both NMOSs 25 and 26 including current block 4 are positive potentials. Thus, NMOSs 25 and 26 are conductive as shown in FIG. 4A. Therefore, the sources of NMOSs 23 and 24 connected to the drains of NMOSs 25 and 26 are at reference potential VSS.

Output retainer 5 functions to retain the potential of output end 33 of level changer 1.

Meanwhile, when the system is in a standby mode and the potential of low voltage power supply VDD1 is switched to reference potential VSS, levels of the output ends 31 and 32 of first and second CMOS inverters 2 and 3 become unstable occasionally. This causes a phenomenon where NMOSs 23, NMOSs 24, PMOSs 13 and PMOSs 14 are in weak conductive state. By this phenomenon, shoot-through current Iₚ tries to flow from high voltage power supply VDD2 to reference potential VSS. The shoot-through current flows in a path via PMOS 13 and NMOS 23 and in a path via PMOS 14 and NMOS 24.

However, a shoot-through current Iₚ does not flow as shown in FIG. 4B, and NMOSs 23, NMOSs 24, PMOSs 13 and PMOSs 14 are non-conductive in the embodiment. It is because the gate-source voltages of NMOSs 25 and 26 including current block 4 are 0 when the potential of low voltage power supply VDD1 is switched to reference potential VSS.

The shoot-through currents which tried to flow from high voltage power supply VDD2 to reference potential VSS through a path of PMOS 13 and NMOS 23 and a path of PMOS 14 and NMOS 24 are blocked.

In the present embodiment, the shoot-through currents will not flow in level changer 1 even when the potential of low voltage power supply VDD1 is switched to reference potential VSS.

When both PMOS 14 and NMOS 24 are weakly conductive, impedance is high in output end 33 of level changer 1. Feedback inverter 7 of output retainer 5 returns a reverse signal (the level of output end 33) of output signal OUT to output end 33 immediately before the potential of low voltage power supply VDD1 is switched to reference potential VSS.

Since the driving force of feedback inverter 7 is stronger than the driving forces of weakly conductive PMOS 14 and NMOS 24, output end 33 of level changer 1 is driven by feedback inverter 7. While the potential of low voltage power supply VDD1 is switched to reference potential VSS, the output end 33 of level changer 1 is stably maintained at level immediately before the switching. Thus, output retainer 5 maintains output end 33 of level changer 1 at the level immediately before the system standby during the system standby period. Output signal OUT, the output of output end 33 is also stably maintained at the level immediately before the system standby.

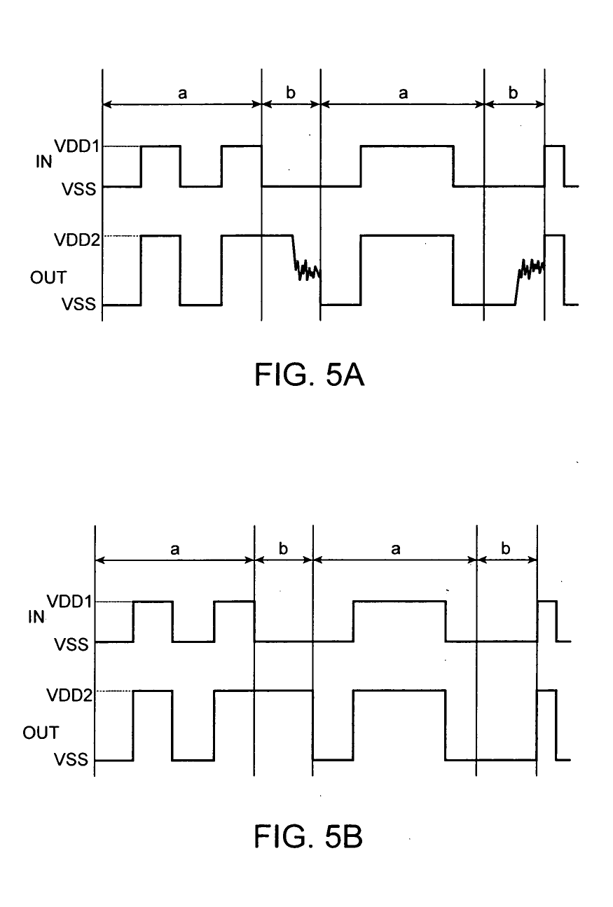

FIGS. 5A and 5B are diagrams showing the effects of output retainer 5 having feedback CMOS inverter 7. FIG. 5A shows waveforms of an output signal OUT of a conventional voltage level shifter without feedback inverter 7. The drawing shows that output signal OUT is unstable during a system standby “b” where the potential of low voltage power supply VDD1 of system operation “a” is switched to reference potential VSS.

FIG. 5B shows waveforms of output signal OUT of the voltage level shifter of the present embodiment having feedback CMOS inverter 7. The drawing shows that output signal OUT maintains the level immediately before switching to the system standby mode during the system standby “b” where the potential of low voltage power supply VDD1 is switched to reference potential VSS.

As described above, unlike the conventional voltage level shifter, the level of output end 33 of level changer 1 is stable even when the potential of low voltage power supply VDD1 is switched to the reference potential VSS. Thus, the output end 33 will not have an unstable intermediate potential, and the shoot-through current will not flow in output CMOS inverter 6 of output retainer 5, into which an output signal of output end 33 of level changer 1 is inputted.

(Second Embodiment)

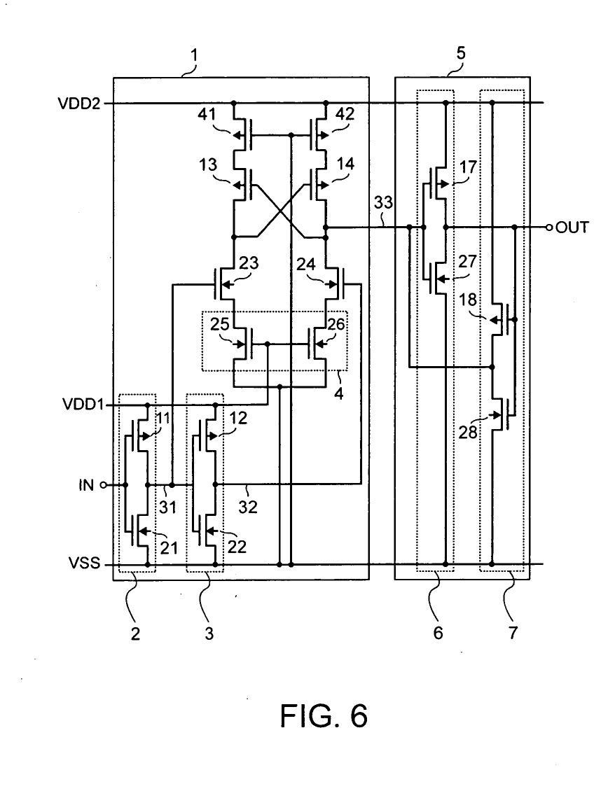

FIG. 6 is a circuit diagram showing the configuration of a voltage level shifter according to a second embodiment of the present invention. In this embodiment, a PMOS 41 is inserted between a source of a PMOS 13 and a high voltage power supply VDD2, and a PMOS 42 is inserted between a source of a PMOS 14 and high voltage power supply VDD2. Gates of both PMOSs 41 and 42 are connected to a reference potential VSS. PMOSs 41 and 42 are constantly conductive. The sources of PMOSs 13 and 14 are constantly given a potential of high voltage power supply VDD2.

The operation of the circuit in the second embodiment shown in FIG. 6 is the same as the operation of the circuit shown in FIG. 3.

As indicated by this embodiment, the sources of PMOSs 13 and 14 do not need to be directly connected to high voltage power supply VDD2 and may be supplied with a potential of high voltage power supply VDD2 through an element such as a PMOS.

In the first and second embodiments, the output retainer 5 is a positive feedback circuit constituted of output CMOS inverter 6 and feedback CMOS inverter 7. The output retainer is not limited to the positive feedback circuit. The output retainer may be any kinds of circuit as long as the circuit can retain the output of the level changer at either the potential of the high voltage power supply or the reference potential when the potential of the low voltage power supply is switched to the reference potential.

In the system mounting the voltage level shifter of the present embodiment therein, voltage level shifter 400 is provided at an input port of microcomputer 200 in FIG. 2. It is not necessary to provide the voltage level shifter inside the microcomputer. The voltage level shifter may be provided outside the microcomputer if the shifter is connected to the input of the internal circuit of the microcomputer.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A voltage level shifter comprising:
a level changer having a current block and a first transistor, in which an input signal having amplitude between a reference potential and a potential of a low voltage power supply higher than the reference potential is inputted into a gate of the first transistor, a high voltage power supply higher than the potential of the low voltage power supply or the current block is connected to a source or a drain of the first transistor, and the level changer outputs a potential of the high voltage power supply or the reference potential by a potential of the input signal inputted into the first transistor; and
an output circuit for outputting an output signal having amplitude between the reference potential and the potential of the high voltage power supply when a signal from an output end of the level changer is inputted thereto.

2. The voltage level shifter according to claim 1,
wherein the current block includes a second transistor in which a source is connected to the reference potential, a drain is connected to the source or the drain of the first transistor, and a gate is connected to the low voltage power supply.

3. The voltage level shifter according to claim 1,
wherein the level changer comprises:
a first input circuit capable of operating by the low voltage power supply, the input signal having the amplitude between the reference potential and the potential of the low voltage power supply higher than the reference potential being inputted into the first input circuit;
a second input circuit capable of operating by the low voltage power supply, an output of the first input circuit being inputted into the second input circuit;
a first N-channel MOSFET, a gate thereof being connected to an output of the first input circuit;
a second N-channel MOSFET, a gate thereof being connected to an output of the second input circuit;
a first P-channel MOSFET, in which a source thereof is connected to the high voltage power supply having a potential higher than the potential of the low voltage power supply, a drain is connected to a drain of the first N-channel MOSFET, and a gate is connected to a drain of the second N-channel MOSFET;
a second P-channel MOSFET, in which a source thereof is connected to the high voltage power supply, a drain is connected to the drain of the second N-channel MOSFET and is set to be the output end of the level changer, and a gate is connected to the drain of the first N-channel MOSFET; and
the current block comprising a third N-channel MOSFET in which a source thereof is connected to the reference potential, a drain is connected to a source of the first N-channel MOSFET, and a gate is connected to the low voltage power supply; and a fourth N-channel MOSFET in which a source thereof is connected to the reference potential, a drain is connected to a source of the second N-channel MOSFET, and a gate is connected to the low voltage power supply.

4. The voltage level shifter according to claim 1, further comprising a retaining circuit for retaining the output end of the level changer at the potential of the high voltage power supply or the reference potential.

5. The voltage level shifter according to claim 4, further comprising an output retainer including the output circuit and the retaining circuit,
wherein the retaining circuit of the output retainer is connected between an output end of the output circuit and the output end of the level changer and is a feedback circuit for returning an output of the output circuit to the output end of the level changer.

6. The voltage level shifter according to claim 5,
wherein both the output circuit and the feedback circuit include CMOS inverters.

7. The voltage level shifter according to claim 4,
wherein time required for the returning by the output circuit and the feedback circuit is shorter than time for output transition of the level changer.

8. A system mounting a voltage level shifter therein, the system comprising a peripheral circuit, the voltage level shifter connected to the peripheral circuit, and an internal circuit connected to the level shifter,
wherein the voltage level shifter comprises:
a level changer having a current block and a first transistor, in which an input signal having amplitude between a reference potential and a potential of a low voltage power supply higher than the reference potential is inputted into a gate of the first transistor from the peripheral circuit, a high voltage power supply higher than the potential of the low voltage power supply or a current block is connected to a source or a drain of the first transistor, and the level changer outputs a potential of the high voltage power supply or the reference potential by a potential of the input signal inputted into the first transistor; and
an output circuit for outputting an output signal having amplitude between the reference potential and the potential of the high voltage power supply to the internal circuit when a signal from an output end of the level changer is inputted thereto.

9. The system according to claim 8,
wherein the internal circuit is supplied with the potential of the high voltage power supply, and the peripheral circuit is supplied with the potential of the low voltage power supply.

10. The system according to claim 9,
wherein the peripheral circuit has a system operation period and a standby period, in which the potential of the low voltage power supply supplied to the peripheral circuit is switched to the reference potential and the potential of the low voltage power supply supplied to the voltage level shifter is switched to the reference potential during the standby period.

11. The system according to claim 8,
wherein the current block includes a second transistor in which a source is connected to the reference potential, a drain is connected to the source or the drain of the first transistor, and a gate is connected to the low voltage power supply.

12. The system according to claim 8,
wherein the level changer comprises:
a first input circuit capable of operating by the low voltage power supply, the input signal having the amplitude between the reference potential and the potential of the low voltage power supply higher than the reference potential being inputted into the first input circuit;
a second input circuit capable of operating by the low voltage power supply, an output of the first input circuit being inputted into the second input circuit;
a first N-channel MOSFET, a gate thereof being connected to an output of the first input circuit;
a second N-channel MOSFET, a gate thereof being connected to an output of the second input circuit;
a first P-channel MOSFET, in which a source thereof is connected to the high voltage power supply having a potential higher than the potential of the low voltage power supply, a drain is connected to a drain of the first N-channel MOSFET, and a gate is connected to a drain of the second N-channel MOSFET;
a second P-channel MOSFET, in which a source thereof is connected to the high voltage power supply, a drain is connected to the drain of the second N-channel MOSFET and is set to be the output end of the level changer, and a gate is connected to the drain of the first N-channel MOSFET; and
the current block comprising a third N-channel MOSFET in which a source thereof is connected to the reference potential, a drain is connected to a source of the first N-channel MOSFET, and a gate is connected to the low voltage power supply; and a fourth N-channel MOSFET in which a source thereof is connected to the reference potential, a drain is connected to a source of the second N-channel MOSFET, and a gate is connected to the low voltage power supply.

13. The system according to claim 8,
wherein the level shifter further comprises a retaining circuit for retaining the output end of the level changer at the potential of the high voltage power supply or the reference potential.

14. The system according to claim 13,
wherein the level shifter further comprises an output retainer including the output circuit and the retaining circuit, and
the retaining circuit of the output retainer is connected between an output end of the output circuit and the output end of the level changer and is a feedback circuit for returning an output of the output circuit to the output end of the level changer.

15. The system according to claim 14,
wherein both the output circuit and the feedback circuit include CMOS inverters.

16. The system according to claim 14,
wherein time required for the returning by the output circuit and the feedback circuit is shorter than time for output transition of the level changer.

17. The system according to claim 8, comprising a microcomputer including the voltage level shifter and the internal circuit.
